(19) United States
(12) Patent Application Publication
(10) Pub. No.: US 2024/0188341 A1
(43) Pub. Date: Jun. 6, 2024

(54) DISPLAY DEVICE

(71) Applicant: LG Display Co., Ltd., Seoul (KR)

(72) Inventors: Seung Han PAEK, Paju-si (KR); Yong In PARK, Paju-si (KR); Hyun Jin AN, Paju-si (KR); Kyung Jae YOON, Paju-si (KR); Jeon Phill HAN, Paju-si (KR); Yu Cheol YANG, Paju-si (KR)

(21) Appl. No.: 18/522,390

(22) Filed: Nov. 29, 2023

(30) Foreign Application Priority Data
Dec. 2, 2022 (KR) 10-2022-0166375
Sep. 5, 2023 (KR) 10-2023-0117810

(51) Int. Cl. H10K 59/122; H10K 59/80

(52) U.S. Cl. CPC H10K 59/122; H10K 59/873

(57) ABSTRACT

Embodiments disclose a display device including a substrate including a display area, a light-transmitting area, and a non-display area surrounding the light-transmitting area, a circuit portion and a light-emitting element portion disposed in the display area, an etch stop layer disposed in the non-display area, and a plurality of protruding patterns disposed in the non-display area, wherein the substrate includes a first opening disposed at a position corresponding to the light-transmitting area, and the plurality of protruding patterns are disposed on the etch stop layer.

### CROSS-REFERENCE TO RELATED APPLICATION

This application claims priority to and the benefit of Korean Patent Applications No. 10-2022-0166375, filed on Dec. 2, 2022, and No. 10-2023-0117810, filed on Sep. 5, 2023, the disclosure of which is incorporated herein by reference in its entirety.

### BACKGROUND

### Technical Field

Embodiments relate to a display device.

### Description of the Related Art

Electroluminescence display devices are classified into inorganic light-emitting display devices and organic light-emitting display devices depending on materials of an emission layer. An active-matrix-type organic light-emitting display device includes an organic light-emitting diode (OLED) that emits light by itself and has advantages of a quick response time, high luminous efficiency, high luminance, and a wide viewing angle. The organic light-emitting display device has OLEDs formed in each pixel. The organic light-emitting display device not only has a quick response time, high luminous efficiency, high luminance, and a wide viewing angle, but also represents a black grayscale as perfect black, and thus has an excellent contrast ratio and color gamut.

### BRIEF SUMMARY

Recently, organic light-emitting display devices have been implemented on a plastic substrate, which is a flexible material. The inventors of the present disclosure have appreciated that there are some benefits to have the display devices implemented on a glass substrate due to various issues. However, the inventors have also recognized that when the organic light-emitting display devices are implemented on the glass substrates, there is a technical problem that rigidity is reduced when processing notches or rounds or forming holes in a panel and it is difficult to process various shapes. Various embodiments of the present disclosure provide display devices addressing the various technical problems in the related art including the above-identified problem.

For example, embodiments provide a display device that maintains rigidity while processing a glass substrate and forming holes of various shapes.

Embodiments provide a display device in which delamination around a hole is improved.

It should be noted that the object of the present disclosure is not limited to the above-described object, and other objects of the present disclosure will be apparent to those skilled in the art from the following descriptions.

According to an aspect of the present disclosure, there is provided a display device including a glass substrate including a display area, a light-transmitting area, and a non-display area surrounding the light-transmitting area, a circuit portion and a light-emitting element portion disposed in the display area, an etch stop layer disposed in the non-display area, and a plurality of protruding patterns disposed in the non-display area, wherein the glass substrate includes a first opening disposed at a position corresponding to the light-transmitting area, and the plurality of protruding patterns are disposed on the etch stop layer.

Each of the plurality of protruding patterns may have an undercut shape.

Each of the plurality of protruding patterns may have the same layer structure as a source electrode of the circuit portion.

The etch stop layer may include a protrusion protruding toward an inner side of the first opening.

The etch stop layer may include one or more of an organic insulating layer, an inorganic insulating layer, and a metal layer.

The display device may include a dam disposed in the non-display area, wherein the plurality of protruding patterns may include a plurality of first protruding patterns disposed between the display area and the dam, a plurality of second protruding patterns disposed between the dam and the etch stop layer, and a plurality of third protruding patterns disposed on the etch stop layer.

The plurality of first protruding patterns, the plurality of second protruding patterns, and the plurality of third protruding patterns may have the same shape.

At least one among the plurality of first protruding patterns, the plurality of second protruding patterns, and the plurality of third protruding patterns may include a different shape or material.

The plurality of first protruding patterns may include a metal layer, and the plurality of third protruding patterns may include an organic insulating layer.

The organic insulating layer of the plurality of third protruding patterns may be a dummy layer of a bank layer in the display area.

The plurality of first protruding patterns may include an inorganic insulating layer, and the plurality of third protruding patterns may include a metal layer.

Each of the plurality of first protruding patterns may include a first pattern layer, and a second pattern layer disposed on the first pattern layer, wherein the first pattern layer may be an inorganic insulating layer, and the second pattern layer may be an organic insulating layer.

The display device may include a side coating layer disposed in the first opening, and a back coating layer disposed on a lower surface of the glass substrate and a lower surface of the side coating layer.

The lower surface of the side coating layer may have a curvature.

According to another aspect of the present disclosure, there is provided a display device including a glass substrate including a display area, a light-transmitting area, and a non-display area surrounding the light-transmitting area, a circuit portion and a light-emitting element portion disposed in the display area, an etch stop layer disposed in the non-display area, and a plurality of protruding patterns disposed in the non-display area, wherein the glass substrate includes a first opening disposed at a position corresponding to the light-transmitting area, cach of the plurality of protruding patterns includes a first pattern layer, a third pattern layer, and a second pattern layer disposed between the first pattern layer and the third pattern layer, a width of the second pattern layer is less than a width of each of the first pattern layer and the third pattern layer.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a conceptual diagram of a display device according to one embodiment of the present disclosure;

FIG. 2 is a cross-sectional view taken along line I-I′ of FIG. 1;

FIG. 3 is an enlarged view of portion A of FIG. 2;

FIG. 4 is an enlarged view of portion B of FIG. 2;

FIG. 5A is a modified example of FIG. 3;

FIG. 5B is a modified example of FIG. 4;

FIG. 6 is a view illustrating etch stop layers surrounding a light-transmitting area and an edge area of a substrate;

FIG. 7 is a cross-sectional view taken along line II-II′ of FIG. 1;

FIG. 8 is an enlarged view of portion C of FIG. 6;

FIG. 9 is an enlarged view of portion D of FIG. 8;

FIG. 10 is a view illustrating a display device according to a first embodiment of the present disclosure;

FIG. 11 is an enlarged view of portion E of FIG. 10;

FIG. 12 is an enlarged view of portion F of FIG. 10;

FIG. 13 is a view illustrating a display panel before forming a light-transmitting area;

FIGS. 14A to 14E are views illustrating a process of etching a substrate to form a light-transmitting area in the display panel;

FIG. 15 is a view illustrating a display device according to a second embodiment of the present disclosure;

FIG. 16 is an enlarged view of portion H of FIG. 15;

FIG. 17 is a view illustrating a display device according to a third embodiment of the present disclosure;

FIG. 18 is an enlarged view of portion I of FIG. 17;

FIG. 19 is a view illustrating a display device according to a fourth embodiment of the present disclosure;

FIG. 20 is a view illustrating a display device according to a fifth embodiment of the present disclosure;

FIG. 21 is a view illustrating a display device according to a sixth embodiment of the present disclosure; and

FIG. 22 is a view illustrating a display device according to a seventh embodiment of the present disclosure.

### DETAILED DESCRIPTION

Advantages and features of the present disclosure and implementation methods thereof will be clarified through the following embodiments described with reference to the accompanying drawings. The present disclosure is not limited to the embodiments described below and may be implemented with a variety of different modifications. The embodiments are merely provided to allow those skilled in the art to completely understand the scope of the present disclosure.

The figures, dimensions (e.g., length, width, height, thickness, radius, diameter, area, etc.), ratios, angles, numbers, and the like disclosed in the drawings for describing the embodiments of the present disclosure are merely illustrative and thus the present disclosure is not limited to matters illustrated in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Throughout the specification, like reference numerals refer to substantially like components. Further, in describing the present disclosure, detailed descriptions of well-known technologies will be omitted when it is determined that they may unnecessarily obscure the gist of the present disclosure.

Terms such as “including,” “having,” and “composed of” used herein are intended to allow other elements to be added unless the terms are used with the term “only.” When a component is expressed in the singular form, it may be construed as the plural form unless otherwise explicitly stated.

Components are interpreted to include an ordinary error range even if not expressly stated.

When the positional or interconnected relationship between two components is described using the terms such as “on,” “above,” “below,” “next to,” “connect or couple,” “crossing or intersecting,” and the like, one or more other components may be interposed between the two components unless the terms are used with the term “immediately” or “directly.”

When the temporal order relationship is described using the terms such as “after,” “subsequent to,” “next,” “before,” and the like, a case which is not continuous may be included unless the term “immediately” or “directly” is used.

To distinguish between components, ordinal numbers such as first, second, and the like may be used before the name of the component, but the function or structure is not limited by these ordinal numbers or component names. For convenience of description, different embodiments may have different ordinal numbers preceding the names of the same component.

The following embodiments may be partially or entirely coupled to or combined with each other and may be interoperated and performed in technically various ways. Each of the embodiments may be independently operable with respect to each other and may be implemented together in related relationships.

Hereinafter, various embodiments of the present disclosure will be described in detail with reference to the accompanying drawings.

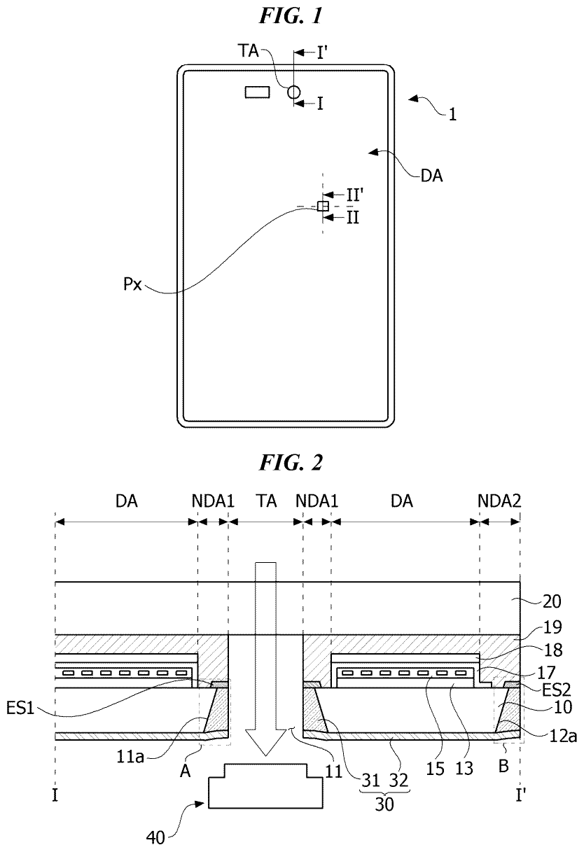

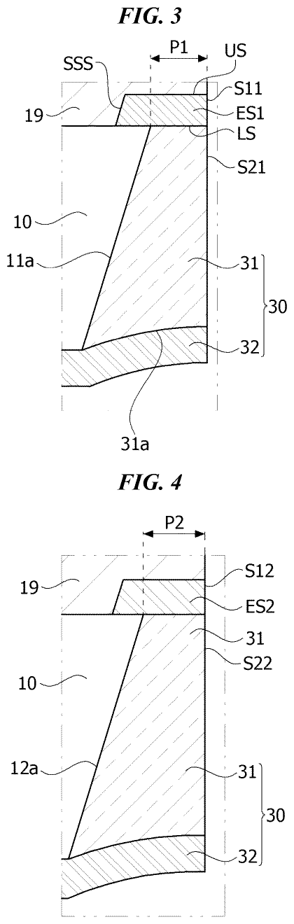

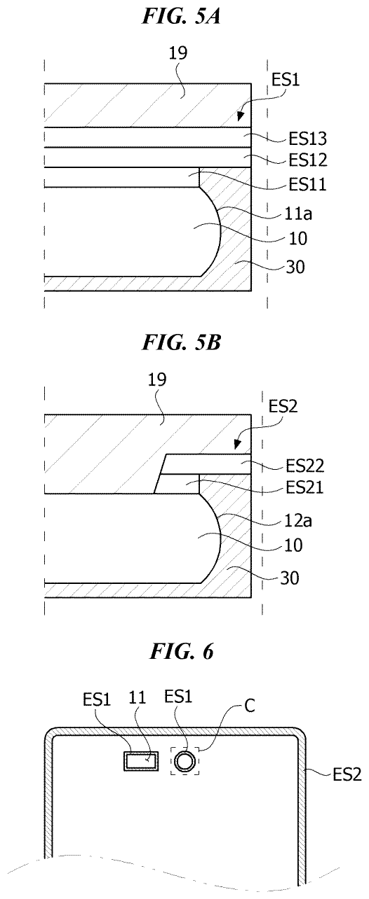

FIG. 1 is a conceptual diagram of a display device according to one embodiment of the present disclosure. FIG. 2 is a cross-sectional view taken along line I-I′ of FIG. 1. FIG. 3 is an enlarged view of portion A of FIG. 2. FIG. 4 is an enlarged view of portion B of FIG. 2. FIG. 5A is a modified example of FIG. 3. FIG. 5B is a modified example of FIG. 4.

Referring to FIGS. 1 and 2, a display device 1 may include a display area DA from which an image is output and a light-transmitting area TA through which light is incident. The light-transmitting area TA may have a hole structure for allowing light to be incident on a sensor 40 disposed below a display panel, but the present disclosure is not necessarily limited thereto.

The display panel may include a circuit portion 13 disposed on a substrate 10, and a light-emitting element portion 15 disposed on the circuit portion 13. A polarizing plate 19 may be disposed on the light-emitting element portion 15, and a cover glass 20 may be disposed on the polarizing plate 19. In addition, a touch portion 18 may be disposed between the light-emitting element portion 15 and the polarizing plate 19.

According to the embodiment, the substrate 10 may be a glass substrate having a predetermined strength. However, the substrate 10 is not necessarily limited thereto, may include a flexible material such as polyimide.

The circuit portion 13 may include a pixel circuit connected to wirings such as data lines, gate lines, power lines, and the like, a gate driving portion connected to the gate lines, and the like.

The circuit portion 13 may include circuit elements such as a transistor implemented as a thin-film transistor (TFT), a capacitor, and the like. The wirings and circuit elements of the circuit portion 13 may be implemented with a plurality of insulating layers, two or more metal layers separated from each other with the insulating layers therebetween, and an active layer including a semiconductor material.

The light-emitting element portion 15 may have a device structure such as an organic light-emitting diode (OLED) display, a quantum dot display, a micro light-emitting diode (LED) display, or the like. Hereinafter, an OLED structure including an organic compound layer will be described as an example.

The organic compound layer may include a hole injection layer HIL, a hole transport layer HTL, an emission layer EML, an electron transport layer ETL, and an electron injection layer EIL, but the present disclosure is not limited thereto.

When a voltage is applied to an anode and a cathode of an OLED, holes passing through the hole transport layer HTL and electrons passing through the electron transport layer ETL move to the emission layer EML to create excitons, and thus visible light may be emitted from the emission layer EML.

The light-emitting element portion 15 may further include a color filter array disposed on pixels that selectively transmit light of red, green, and blue wavelengths.

The light-emitting element portion 15 may be covered by a protective film, and the protective film may be covered by an encapsulation portion 17. The protective film and the encapsulation portion 17 may have a structure in which organic insulating layers and inorganic insulating layers are alternately stacked. The inorganic insulating layer may block the penetration of moisture or oxygen. The organic insulating layer may planarize a surface of the inorganic insulating layer. Thus, when the organic and inorganic insulating layers are stacked in multiple layers, a moving path of the moisture or oxygen is longer compared to a single layer, so that the penetration of moisture/oxygen affecting the light-emitting element portion 15 may be effectively blocked.

The polarizing plate 19 may be disposed on the light-emitting element portion 15. The polarizing plate 19 can improve outdoor visibility of the display device. The polarizing plate 19 may reduce light reflected from a surface of the display panel and block light reflected from the metal of the circuit portion 13 to improve the brightness of the pixels.

The light-transmitting area TA may be formed between the display areas DA. A first non-display area NDA1 may be disposed to surround the light-transmitting area TA. The first non-display area NDA1 may include a structure of a plurality of dams to protect light-emitting elements in the display area DA from moisture or oxygen that may be introduced from the light-transmitting area TA.

The light-transmitting area TA may have a through-hole structure for injecting light into the sensor 40 such as a camera. However, the present disclosure is not necessarily limited thereto, and pixels having a low density may be disposed in the light-transmitting area TA.

The substrate 10 may include a first opening 11 disposed in the light-transmitting area TA. The first opening 11 may have a tapered shape that narrows in width as it approaches the cover glass 20. However, the first opening 11 is not necessarily limited thereto, and may have a tapered shape that increases in width as it approaches the cover glass 20, or may be constant in width in a thickness direction. The tapered shape of the first opening 11 may be variously changed by the type of an etching solution and an etching method.

A first etch stop layer ES1 may be disposed on the first opening 11 of the substrate 10. In addition, a second etch stop layer ES2 may be disposed on an edge of the substrate 10. The first etch stop layer ES1 and the second etch stop layer ES2 may prevent an etching solution from penetrating into the panel when etching the substrate 10.

The first etch stop layer ES1 and the second etch stop layer ES2 may include an organic material that is resistant to an etching solution. As an example, the etch stop layer may include one selected from the group consisting of a polyester-based polymer, a silicone-based polymer, an acrylic-based polymer, a polyolefin-based polymer, and a copolymer thereof. However, the etch stop layer is not necessarily limited thereto, and may include various materials that are resistant to the etching solution.

The first etch stop layer ES1 and the second etch stop layer ES2 may be formed by extending from at least one of the layers constituting the circuit portion 13, the light-emitting element portion 15, the encapsulation portion 17, and the touch portion 18. That is, the first etch stop layer ES1 and the second etch stop layer ES2 may be dummy layers of the circuit portion 13, the light-emitting element portion 15, the encapsulation portion 17, or the touch portion 18. With this configuration, the etch stop layer may be formed without adding a separate process.

According to the embodiment, the first etch stop layer ES1 may include a protrusion P1 protruding toward an inner side of the first opening 11. The protrusion P1 may be defined as a portion more protruding toward the light-transmitting area TA than an upper surface of the first opening 11. The protrusion P1 may be formed in a process of laser cutting the etch stop layer.

As shown in FIG. 3, the substrate 10 includes an opening 11. The light-transmitting area of the substrate 10 overlaps with the opening 11 of the substrate 10 from a plan view. Here, an etch stop layer ES1 is adjacent to the opening 11. As shown in FIG. 3, the coating layer 30 is between the etch stop layer ES1 and the substrate 10. In some embodiments, the etch stop layer ES1 is on both the substrate 10 and the coating layer 30. The etch stop layer ES1 has an upper surface US, a lower surface LS, and a side surface SSS between the upper surface US and the lower surface LS. In some embodiments, the lower surface LS of the etch stop layer ES1 directly contacts the substrate 10 and the coating layer 30.

Further, as shown, a polarizing plate 19 may be on the substrate 10 and the coating layer 30. In some embodiments, the polarizing plate 19 directly may contact the upper surface US and the side surface SSS of the etch stop layer ES1. However, the present disclosure is not necessarily limited thereto

A coating layer 30 may be formed on a back surface of the substrate 10. For example, the coating layer 30 may be formed of an organic material including a polyester-based polymer or an acrylic-based polymer.

The coating layer 30 may include a side coating layer 31 formed on an inner side surface of the first opening 11, and a back coating layer 32 disposed on a lower portion of the substrate. A lower surface 31a of the side coating layer 31 may be formed to be concave toward the etch stop layer. However, the side coating layer 31 is not necessarily limited thereto, and may not be contracted depending on the material. Thus, the lower surface 31a of the side coating layer 31 may be substantially flat even after curing is completed.

A first inclined surface 11a of the first opening 11 and a side surface S11 of the protrusion P1 of the first etch stop layer may have different inclinations. As an example, an inclination angle of the side surface S11 of the protrusion P1 may be greater than an inclination angle of the first inclined surface 11a. For example, the inclination angle of the side surface S11 may be 90 degrees, and inclination angle of the first inclined surface 11a may be an acute angle. This is because the first opening 11 is etched by an etching solution and has a tapered shape, while the first etch stop layer ES1 is cut by a laser to form a relatively vertical cross section. A side surface S21 of the coating layer 30 disposed below the protrusion P1 may have the same inclination angle as the side surface S11 of the protrusion P1.

However, the present disclosure is not necessarily limited thereto, and the first inclined surface 11a may be the same as an inclination of the side surface of the first etch stop layer ES1. Alternatively, the first inclined surface 11a may have a rounded shape.

Referring to FIGS. 2 and 4, a second non-display area NDA2 may be disposed at an edge of the display panel. The second non-display area NDA2 may be a margin portion required to divide a mother substrate into a plurality of panels.

The substrate 10 may include a second inclined surface 12a formed at the edge thereof. The second inclined surface 12a may have the same angle as the first inclined surface 11a formed in the first opening 11. The first opening 11 and the second inclined surface 12a are formed simultaneously by an etching solution, so that the first opening 11 and the second inclined surface 12a may have the same inclination angle and etching depth.

According to the embodiment, the first opening 11 may be formed in a substrate of cach display panel simultaneously in a process of separating a plurality of display panels by etching a mother substrate. Accordingly, the opening may be formed without additional equipment and without reducing rigidity. In addition, various shapes of openings may be formed by changing a mask pattern.

The second etch stop layer ES2 disposed in the second non-display area NDA2 may prevent an etching solution from penetrating into a plurality of display panels when etching a mother substrate to separate the plurality of display panels.

The second etch stop layer ES2 may extend from at least one of the layers of the circuit portion 13, the light-emitting element portion 15, the encapsulation portion 17, and the touch portion 18. Alternatively, the second etch stop layer may be formed simultaneously in a process of forming at least one of the layers of the circuit portion 13, the light-emitting element portion 15, the encapsulation portion 17, and the touch portion 18. With this configuration, the second etch stop layer ES2 may be formed without adding a separate process.

According to the embodiment, the second etch stop layer ES2 may include a protrusion P2 protruding outwardly from the second inclined surface 12a. The protrusion P2 may prevent damage to the display panel when laser cutting the second etch stop layer ES2.

A side surface S22 of the coating layer 30 disposed below the protrusion P2 may have the same inclination angle as a side surface S12 of the protrusion P2.

Referring to FIG. 5A, the first etch stop layer ES1 may include first to third sub-layers ES11, ES12, and ES13. The first sub-layer ES11 may be an inorganic insulating layer, and the third sub-layer ES13 may be an organic insulating layer. Since an adhesion between the organic insulating layer and the substrate 10 is relatively weak, the adhesion between the organic insulating layer and the substrate 10 may be improved by the inorganic insulating layer. The inorganic insulating layer may be etched when the inorganic insulating layer is in contact with the etching solution during the process of etching the substrate.

The second sub-layer ES12 may be a metal layer. The second sub-layer ES12 may include molybdenum (Mo) or the like, which has relatively greater chemical resistance to an etching solution as compared to the first sub-layer ES11. However, the present disclosure is not necessarily limited thereto, and the second sub-layer ES12 may be omitted in some cases.

The first opening 11 may be entirely filled with the coating layer 30. Accordingly, when the first etch stop layer ES1 is cut by a laser, the coating layer 30 formed in the first opening 11 may be cut to have the same cross section as the first etch stop layer ES1. Thus, the cross section of the first etch stop layer ES1 and the cross section of the coating layer 30 formed in the first opening 11 may be coplanar with each other.

In the substrate 10, the first inclined surface 11a may have a rounded shape rather than a tapered shape. That is, as the first sub-layer ES11 is etched to expose an upper surface of the substrate, the upper surface of the substrate is also etched so that the first inclined surface 11a of the opening may have a rounded shape.

Referring to FIG. 5B, the second etch stop layer ES2 may include a first sub-layer ES21 and a second sub-layer ES22. The first sub-layer ES21 may be an inorganic insulating layer, and the second sub-layer ES22 may be an organic insulating layer. However, the present disclosure is not necessarily limited thereto, and the second etch stop layer may have the layer structure as shown in FIG. 5A.

The first etch stop layer ES1 and the second etch stop layer ES2 may have the same layer structure or different layer structures. As an example, some layers in the display area DA may be extendable to the first non-display area NDA1, but may be difficult to extend to the second non-display area NDA2. In this case, the first etch stop layer ES1 and the second etch stop layer ES2 may have different layer structures.

In addition, the first etch stop layer ES1 may be formed by continuously extending from the display area DA, while the second etch stop layer ES2 may be formed to be disconnected from the display area DA. Alternatively, in contrast thereto, the second etch stop layer ES2 may be formed to extend from the display area DA, while the first etch stop layer ES1 may be formed to be disconnected from the display area DA.

FIG. 6 is a view illustrating a shape in which the etch stop layer surrounds the light-transmitting area.

Referring to FIG. 6, the first etch stop layer ES1 may be disposed to entirely surround the periphery of the first opening 11. In addition, the second etch stop layer ES2 may be disposed to entirely surround an outer circumferential surface of the display panel.

According to the embodiment, since the first etch stop layer ES1 is disposed to entirely surround the periphery of the first opening 11 and the second etch stop layer ES2 is disposed to entirely surround the outer circumferential surface of the display panel, an etching solution may be prevented from penetrating into the panel in a case in which a through hole is formed inside the substrate simultaneously when a mother substrate is cut.

According to the embodiment, the opening of various shapes may be formed in the glass substrate using etching. Thus, compared to conventional scribing, breaking, and grinding techniques, there is an advantage of being able to form various openings while maintaining the rigidity of the substrate. In addition, there is an advantage of being able to form the opening simultaneously when processing the side surface of the substrate 10 to form notches or roundings on the side surface of the substrate 10.

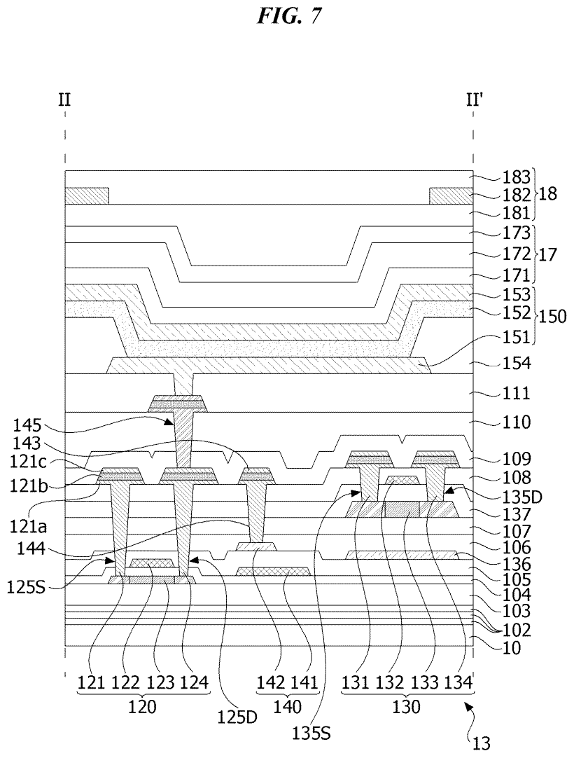

FIG. 7 is a cross-sectional view taken along line II-II′ of FIG. 1.

Referring to FIG. 7, the display area DA may include the substrate 10, a multi-buffer layer 102, and an active buffer layer 103, and a first transistor 120 may be disposed on the active buffer layer 103.

A lower gate insulating layer 104 may be disposed to insulate a first semiconductor layer 123 constituting the first transistor 120 from a first gate electrode 122 on the first semiconductor layer 123. A first lower interlayer insulating layer 105 and a second lower interlayer insulating layer 106 may be sequentially disposed on the first gate electrode 122, and an upper buffer layer 107 may be disposed thercon.

The multi-buffer layer 102 may delay the diffusion of moisture or oxygen penetrating into the substrate 10, and may be formed by alternately stacking silicon nitride (SiNx) and silicon oxide (SiOx) at least once.

An active buffer layer 103 may serve to protect the first semiconductor layer 123, and block various types of defects introduced from the substrate 10. The active buffer layer 103 may be formed of a-Si, silicon nitride (SiNx), silicon oxide (SiOx), or the like.

The first semiconductor layer 123 of the first transistor 120 may be formed of a polycrystalline semiconductor layer, and the first semiconductor layer 123 may include a channel area, a source area, and a drain area.

The polycrystalline semiconductor layer has higher mobility than an amorphous semiconductor layer and an oxide semiconductor layer, and thus has low energy power consumption and excellent reliability. Due to these advantages, the polycrystalline semiconductor layer may be used for a driving transistor.

The first gate electrode 122 may be disposed on the lower gate insulating layer 104 and may be disposed to overlap the first semiconductor layer 123.

A second transistor 130 may be disposed on the upper buffer layer 107, and a light blocking layer 136 may be disposed below an area corresponding to the second transistor 130.

The light blocking layer 136 may be disposed on the first lower interlayer insulating layer 105 in an area corresponding to the second transistor 130, and a second semiconductor layer 133 of the second transistor 130 may be disposed on the second lower interlayer insulating layer 106 and the upper buffer layer 107 so as to overlap the light blocking layer 136.

An upper gate insulating layer 137 for insulating a second gate electrode 132 from the second semiconductor layer 133 may be disposed on the second semiconductor layer 133.

An upper interlayer insulating layer 108 may be disposed on the second gate electrode 132. Each of the first gate electrode 122 and the second gate electrode 132 may be formed as a single layer or a multilayer made of one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first and second lower interlayer insulating layers 105 and 106 may be formed of inorganic insulating layers having a higher hydrogen particle content than the upper interlayer insulating layer 108. For example, the first and second lower interlayer insulating layers 105 and 106 may be made of silicon nitride (SiNx) formed through a deposition process using NH3 gas, and the upper interlayer insulating layer 108 may be made of silicon oxide (SiOx). Hydrogen particles included in the first and second lower interlayer insulating layers 105 and 106 may be diffused into the polycrystalline semiconductor layer during a hydrogenation process to fill pores in the polycrystalline semiconductor layer with hydrogen. Accordingly, the polycrystalline semiconductor layer may be stabilized, thereby preventing degradation in characteristics of the first transistor 120.

After an activation and hydrogenation process of the first semiconductor layer 123 of the first transistor 120, the second semiconductor layer 133 of the second transistor 130 may be formed, and in this case, the second semiconductor layer 133 may be formed of an oxide semiconductor. Since the second semiconductor layer 133 is not exposed to a high-temperature atmosphere of the activation and hydrogenation process of the first semiconductor layer 123, damage to the second semiconductor layer 133 may be prevented, which may improve reliability.

After the upper interlayer insulating layer 108 is disposed, a first source contact hole 125S and a first drain contact hole 125D may be respectively formed to correspond to a source area and a drain area of the first transistor, and a second source contact hole 135S and a second drain contact hole 135D may be respectively formed to correspond to a source region and a drain region of the second transistor 130.

The first source contact hole 125S and the first drain contact hole 125D may be continuously formed from the upper interlayer insulating layer 108 to the lower gate insulating layer 104, and the second source contact hole 135S and the second drain contact hole 135D may also be formed in the second transistor 130.

A first source electrode 121 and a first drain electrode 124 corresponding to the first transistor 120 and a second source electrode 131 and a second drain electrode 134 corresponding to the second transistor 130 may be formed at the same time, thereby reducing the number of processes of forming the source and drain electrodes of each of the first transistor 120 and the second transistor 130.

The first source and drain electrodes 121 and 124 and the second source and drain electrodes 131 and 134 may be formed as a single layer or a multilayer made of at least one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

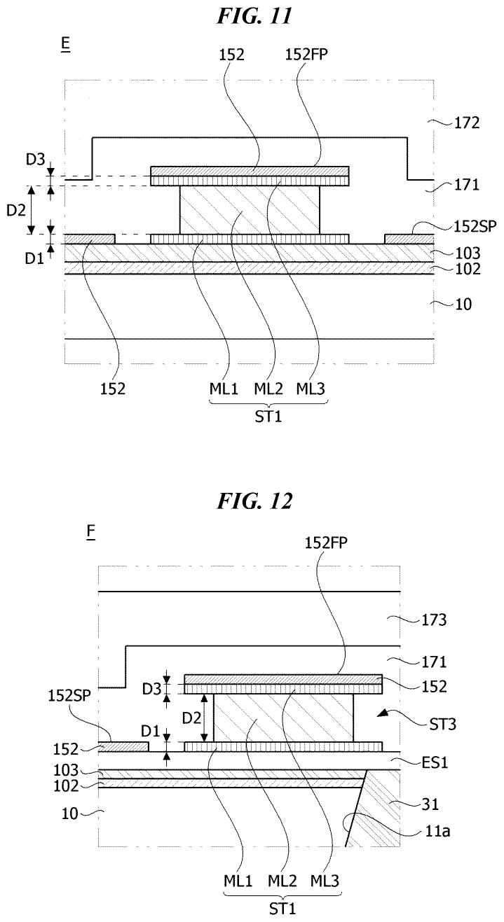

The first source and drain electrodes 121 and 124, a connection electrode 145, and the second source and drain electrodes 131 and 134 may have a three-layered structure, and for example, the first source electrode 121 may include a first layer 121a, a second layer 121b, and a third layer 121c, and other source and drain electrodes may have the same structure as the first source electrode 121. In some embodiments, the protruding patterns ST have a same layer structure as a source electrode or the connection electrode 145 of the circuit portion. For instance, the protruding patterns ST also has a three-layered structure. As shown in FIG. 11, the protruding patterns ST may cach have a first pattern layer ML1 having a first thickness D1, a second pattern layer ML2 having a second thickness D2, and a third pattern layer ML3 having a third thickness D3 stacked in sequence.

A storage capacitor 140 may be disposed between the first transistor 120 and the second transistor 130. The storage capacitor 140 may be formed by overlapping a storage lower electrode 141 and a storage upper electrode 142 with the first lower interlayer insulating layer 105 interposed therebetween.

The storage lower electrode 141 may be located on the lower gate insulating layer 104, formed on the same layer as the first gate electrode 122, and made of the same material as the first gate electrode 122. The storage upper electrode 142 may be electrically connected to a pixel circuit through a storage supply line 143. The storage upper electrode 142 may be formed on the same layer as the light blocking layer 136 and made of the same material as the light blocking layer 136. The storage upper electrode 142 is exposed through a storage contact hole 144 passing through the second lower interlayer insulating layer 106, the upper buffer layer 107, the upper gate insulating layer 137, and the upper interlayer insulating layer 108 and is connected to the storage supply line 143.

The storage upper electrode 142 is spaced apart from the light blocking layer 136, but the storage upper electrode 142 and the light blocking layer 136 may also be formed as an integrated body in which they are connected to each other. The storage supply line 143 may be formed to be coplanar with the first source and drain electrodes 121 and 124 and the second source and drain electrodes 131 and 134 and made of the same material as the first source and drain electrodes 121 and 124 and the second source and drain electrodes 131 and 134, and accordingly, the storage supply line 143 may be formed simultaneously with the first source and drain electrodes 121 and 124 and the second source and drain electrodes 131 and 134 through the same mask process.

A protective film 109 may be formed by depositing an inorganic insulating material such as SiNx or SiOx on an entire surface of the substrate 10 on which the first source and drain electrodes 121 and 124, the second source and drain electrodes 131 and 134, and the storage supply line 143 are formed.

A first planarization layer 110 may be formed on the protective film 109. Specifically, the first planarization layer 110 may be disposed by applying an organic insulating material such as an acrylic-based resin onto the entire surface of the protective film 109.

After the protective film 109 and the first planarization layer 110 are disposed, a contact hole exposing the first source electrode 121 or the first drain electrode 124 of the first transistor 120 may be formed through a photolithography process. The connection electrode 145 made of a material including Mo, Ti, Cu, AlNd, Al, Cr, or an alloy thereof may be disposed in an area of the contact hole exposing the first drain electrode 124.

A second planarization layer 111 may be disposed on the connection electrode 145, and a contact hole exposing the connection electrode 145 may be formed in the second planarization layer 111 to arrange a light-emitting element 150 connected to the first transistor 120.

The light-emitting element 150 may include an anode 151 connected to the first drain electrode 124 of the first transistor 120, at least one light-emitting stack 152 formed on the anode 151, and a cathode 153 formed on the light-emitting stack 152.

The light-emitting stack 152 may include a hole injection layer, a hole transport layer, an emission layer, an electron transport layer, and an electron injection layer, and in a tandem structure in which a plurality of emission layers overlap each other, a charge generation layer may be additionally disposed between the emission layer and the emission layer. The emission layers may emit different colors for respective sub-pixels.

The anode 151 may be connected to the connection electrode 145 exposed through a contact hole passing through the second planarization layer 111. The anode 151 may be formed in a multi-layered structure including a transparent conductive film and an opaque conductive film having high reflection efficiency. The transparent conductive film may be made of a material having a relatively large work function value, such as indium-tin-oxide (ITO) or indium-zinc-oxide (IZO), and the opaque conductive film may have a single-layered or multi-layered structure including Al, Ag, Cu, Pb, Mo, Ti, or an alloy thereof.

For example, the anode 151 may be formed in a structure in which a transparent conductive film, an opaque conductive film, and a transparent conductive film are sequentially stacked or in a structure in which a transparent conductive film and an opaque conductive film are sequentially stacked.

The anode 151 may be disposed in an emission area provided by a bank 154 as well as on the second planarization layer 111 to overlap a pixel circuit area in which the first and second transistors 120 and 130 and the storage capacitor 140 are disposed, thereby increasing an area for emitting light.

The light-emitting stack 152 may be formed by stacking the hole transport layer, the organic emission layer, and the electron transport layer on the anode 151 in this order or in a reverse order. In addition, the light-emitting stack 152 may further include a charge generation layer and may include first and second light-emitting stacks facing each other with the charge generation layer interposed therebetween.

The bank 154 may be formed to expose the anode 151. The bank 154 may be made of an organic material such as photoacrylic and may include a translucent material, but the present disclosure is not limited thereto. The bank 154 may be made of an opaque material to prevent light interference between the subpixels.

The cathode 153 may be formed on an upper surface of the light-emitting stack 152 to face the anode 151 with the light-emitting stack 152 interposed therebetween. When the cathode 153 is applied to a top emission type organic light-emitting display device, the cathode 153 may be formed of a transparent conductive film by thinly forming ITO, IZO, or magnesium-silver (Mg—Ag).

The encapsulation portion 17 for protecting the light-emitting element 150 may be formed on the cathode 153. Since the light-emitting element 150 reacts with external moisture or oxygen due to the characteristics of an organic material of the light-emitting stack 152, dark-spots or pixel shrinkage may occur. In order to prevent the dark-spots or pixel shrinkage, the encapsulation portion 17 may be disposed on the cathode 153.

The encapsulation portion 17 may include a first inorganic insulating layer 171, a foreign material compensation layer 172, and a second inorganic insulating layer 173.

The touch portion 18 may be disposed on the encapsulation portion 17. The touch portion 18 may include a first touch planarization layer 181, a touch electrode 182, and a second touch planarization layer 183. The first touch planarization layer 181 and the second touch planarization layer 183 may be disposed to eliminate a stepped portion at a point at which the touch electrode 182 is disposed and to allow the touch electrode 182 to be electrically insulated well.

According to embodiments, by disposing the first transistor 120 made of low-temperature polycrystalline silicon and the second transistor 130 made of an oxide semiconductor in different layers, thin-film transistors (TFTs) having different driving characteristics may be disposed in the display device 1. However, the present disclosure is not necessarily limited thereto, and only the thin-film transistors having the same driving characteristic may be used.

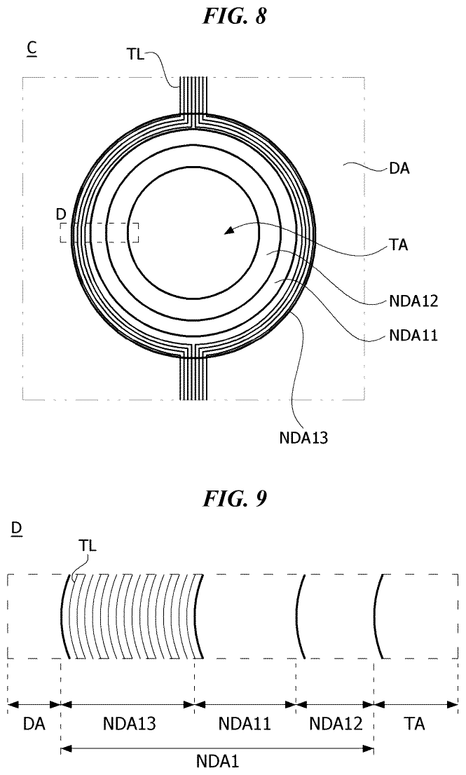

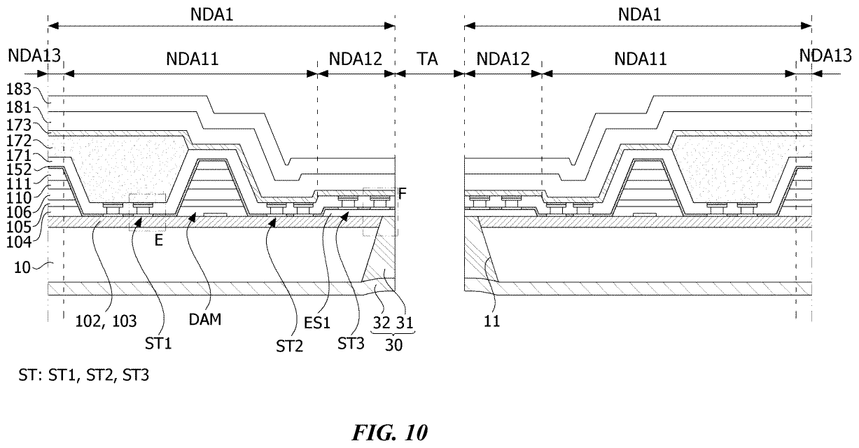

FIG. 8 is an enlarged view of portion C of FIG. 6. FIG. 9 is an enlarged view of portion D of FIG. 8. FIG. 10 is a view illustrating a display device according to a first embodiment of the present disclosure. FIG. 11 is an enlarged view of portion E of FIG. 10. FIG. 12 is an enlarged view of portion F of FIG. 10.

Referring to FIGS. 8 and 9, the light-transmitting area TA in which various sensors are disposed may be formed in a circular shape, and the first non-display area NDA1 may be disposed around the light-transmitting area. However, the light-transmitting area TA is not necessarily limited thereto, and may have various shapes such as a polygonal shape and an elliptical shape, and the shape of the first non-display area NDA1 may also vary accordingly.

The first non-display area NDA1 may include a wiring area NDA13 in which wirings TL bypassing the light-transmitting area TA are disposed, a moisture-permeating prevention area NDA11 disposed between the wiring area NDA13 and the light-transmitting area TA, and a dummy area NDA12 in which the first etch stop layer ES1 is formed. The moisture-permeating prevention area NDA11 and the dummy area NDA12 may be disposed to surround the light-transmitting area TA. The dummy area NDA12 may also serve to prevent moisture permeation.

Referring to FIG. 10, dams DAM and a plurality of protruding patterns ST may be formed in the moisture-permeating prevention area NDAll by using a plurality of layers extending from a display area. The number of dams DAM and protruding patterns ST is not particularly limited.

The dams DAM and the protruding patterns ST may each be disposed in a closed loop shape surrounding a light-transmitting area TA. With this configuration, moisture can be prevented from penetrating into the display area through the light-transmitting area TA. A width of the moisture-permeating prevention area NDA11 may have a selected distance (or a predetermined distance) to prevent moisture permeation.

The dummy area NDA12 may be an area formed for a margin during etching and/or laser cutting of a substrate 10. Without the dummy area NDA12, the moisture-permeating prevention area NDA11 may be damaged during laser cutting and thus vulnerable to moisture penetration. In addition, the substrate 10 may be damaged by the laser. The dummy area NDA12 may have only minimal layers disposed on the substrate 10 to facilitate laser cutting.

A first etch stop layer ES1 may be disposed in the dummy area NDA12 to prevent an etching solution from penetrating into the panel when the substrate 10 is etched. The first etch stop layer ES1 may include an organic insulating layer or a metal layer which is not etched by the etching solution. The metal layer may include molybdenum (Mo) having strong corrosion resistance to the etching solution.

A plurality of protruding patterns ST may be disposed in the first non-display area NDA1. The protruding pattern ST is formed to have an undercut shape, so that a light-emitting stack 152 formed in the first non-display area NDA1 may be disconnected.

The plurality of protruding patterns ST may include a first protruding pattern ST1 and a second protruding pattern ST2 disposed in the moisture-permeating prevention area NDA11, and a third protruding pattern ST3 disposed in the dummy area NDA12.

A plurality of first protruding patterns ST1 may be disposed between the display area and the dam DAM, and a plurality of second protruding patterns ST2 may be disposed between the dam DAM and the dummy area NDA12. A plurality of third protruding patterns ST3 may be disposed on the first etch stop layer ES1 in the dummy area NDA12.

The plurality of first protruding patterns ST1, the plurality of second protruding patterns ST2, and the plurality of third protruding patterns ST3 may have the same shape, but the present disclosure is not necessarily limited thereto. As an example, the first protruding pattern ST1 and the second protruding pattern ST2 may have the same shape, but the third protruding pattern ST3 may have a different shape. Each of the protruding patterns ST1, ST2, and ST3 may be variously modified as long as it has a structure capable of disconnecting the light-emitting stack 152.

The substrate 10 may have a first opening 11 formed in an area corresponding to the light-transmitting area TA. A diameter of the first opening 11 may be greater than that of the light-transmitting area TA.

A side coating layer 31 may be formed on a side surface of the first opening 11. The side coating layer 31 may cover the side surface of the first opening 11. The first etch stop layer ES1 may be disposed on the side coating layer 31.

The side coating layer 31 may be made of an organic material that absorbs light. In one embodiment, the side coating layer 31 may include an organic material having an optical density (OD) of 1.0 or more.

A back coating layer 32 may be disposed below the substrate 10 and the side coating layer 31. The back coating layer 32 may be formed to further extend from a back surface of the substrate 10 up to the side coating layer 31.

In the display device according to the embodiment, a bonding strength of the back coating layer 32 may be improved by forming the back coating layer 32 to cover up to the side coating layer 31. The back coating layer 32 may be formed only on the back surface of the substrate 10 to protect the substrate 10. However, the back coating layer 32 made of an organic material has a relatively low bonding strength with the substrate 10, and thus may be delaminated from the substrate 10 by an external environment or impact. Thus, the bonding strength of the back coating layer 32 can be improved by allowing the back coating layer 32 to be in contact with the side coating layer 31 made of an organic material at an outer periphery of the substrate 10. Accordingly, the back coating layer 32 can be prevented from delaminating from the substrate 10.

According to the embodiment, a side surface of the light-transmitting area TA may be vertically formed. That is, a side surface of the back coating layer 32, a side surface of the side coating layer 31, a side surface of the first etch stop layer ES1, and a side surface of a polarizing plate 19, which form the side surface of the light-transmitting area TA, may be laser cut and formed to have the same vertical plane.

Referring to FIG. 11, the plurality of protruding patterns ST may each have a first pattern layer ML1, a second pattern layer ML2, and a third pattern layer ML3 stacked in sequence. The first pattern layer ML1 and the third pattern layer ML3 may be made of a titanium (Ti) material, and the second pattern layer ML2 may be made of an aluminum (Al) material.

The protruding pattern ST according to the embodiment may be made of the same material as source and drain electrodes 121 and 124 or a connection electrode 145 in the display area. That is, the plurality of protruding patterns ST may be simultaneously formed when the connection electrode 145 is formed, and then may be etched to be separated into the plurality of protruding patterns ST. At this time, the second pattern layer ML2 made of an aluminum material may be etched relatively more due to the difference in etching reaction speed. Accordingly, a width of the second pattern layer ML2 may be smaller than a width of the third pattern layer ML3, thereby having an undercut shape. Accordingly, the light-emitting stack 152 formed on the plurality of protruding patterns ST may not be continuously formed and may be disconnected between the plurality of protruding patterns ST. Thus, a moisture penetration path can be blocked.

According to the embodiment, the plurality of protruding patterns ST can prevent delamination of an inorganic insulating layer additionally disposed thercon. An inorganic insulating layer may be delaminated relatively easily during laser etching or by an external impact. However, according to the embodiment, since the inorganic insulating layer is filled between the plurality of protruding patterns ST cach having an undercut shape, delamination can be prevented. Thus, the penetration of moisture can be effectively prevented.

Referring to FIG. 12, the protruding pattern ST3 is on the etch stop layer ES1. Here, the protruding pattern ST3 includes a first pattern layer ML1 having a first thickness D1, a second pattern layer ML2 having a second thickness D2, and a third pattern layer ML3 having a third thickness D3. In some embodiments, the second thickness D2 of the second pattern layer ML2 is greater than either the third thickness D3 of the third pattern layer ML3 or the first thickness D1 of the first pattern layer ML1. In some embodiments, the first thickness D1 of the first pattern layer ML1 may have the same thickness as the third thickness D3 of the third pattern layer ML3. In other embodiments, the first thickness D1 of the first pattern layer ML1 may have a different thickness as the third thickness D3 of the third pattern layer ML3. For example, the first thickness D1 of the first pattern layer ML1 may be greater or smaller than the third thickness D3 of the third pattern layer ML3.

Further, as shown, the third pattern layer ML3 fully overlaps the second pattern layer ML2 from a plan view.

In some embodiments, the light-emitting stack 152 is disposed on the protruding pattern ST3. In some embodiments, the light-emitting stack 152 (more specifically, a first portion of the light-emitting stack 152FP) fully overlaps the third pattern layer ML3 from a plan view.

As shown in FIG. 12, in some embodiments, the light-emitting stack 152 on the etch stop layer ES1 and the light-emitting stack includes a first portion 152FP and a second portion 152SP. The second portion 152SP of the light-emitting stack 152 is spaced apart from the first portion 152FP of the light-emitting stack 152. Here, the first portion 152FP of the light-emitting stack is on and contacting the third pattern layer ML3 of the protruding pattern ST3. The second portion 152SP of the light-emitting stack is adjacent to and spaced apart from the first pattern layer ML1 of the protruding pattern ST3.

The insulating layer 171 is on the etch stop layer ES1 and the protruding pattern ST3. In one embodiment, the insulating layer 171 directly contacts the second portion 152SP of the light-emitting stack, the etch stop layer ES1, and the first pattern layer ML1 of the protruding pattern ST3.

Referring to FIG. 12, the plurality of third protruding patterns ST3 may be disposed on the first etch stop layer ES1. Among the plurality of third protruding patterns ST3, the outermostly disposed third protruding pattern ST3 may further protrude toward the light-transmitting area TA than a first inclined surface 11a of the first opening 11 of the substrate 10. However, the present disclosure is not necessarily limited thereto, and the first inclined surface 11a of the first opening 11 of the substrate 10 may further protrude toward the light-transmitting area TA than the third protruding pattern ST3 that is disposed at the outermost side among the third protruding patterns ST3.

The light-emitting stack 152 formed on the plurality of third protruding patterns ST3 may not be continuously formed and may be disconnected between the plurality of third protruding patterns ST3. Thus, a moisture penetration path can be blocked.

According to the embodiment, by forming the plurality of third protruding patterns ST3 in the dummy area NDA12, the inorganic insulating layer can be prevented from delamination during laser etching or external impact.

The plurality of third protruding patterns ST3 may be directly formed on the first etch stop layer ES1 or may be disposed on a dummy layer disposed on the first etch stop layer ES1.

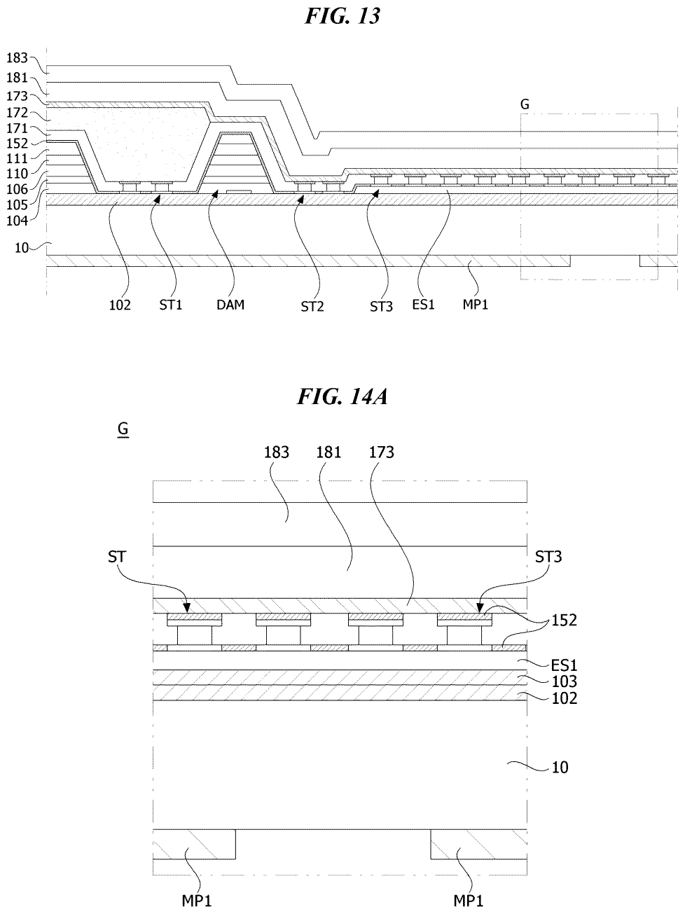

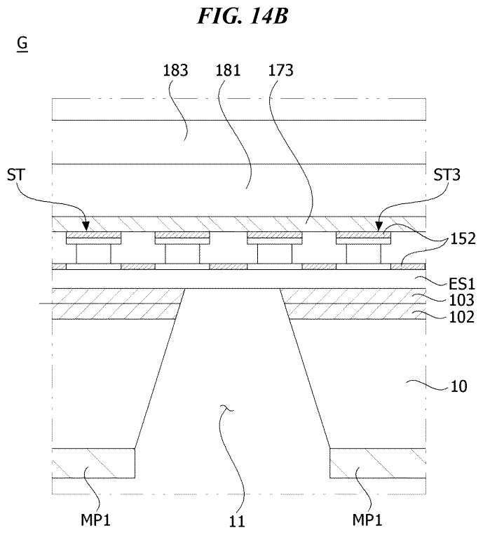

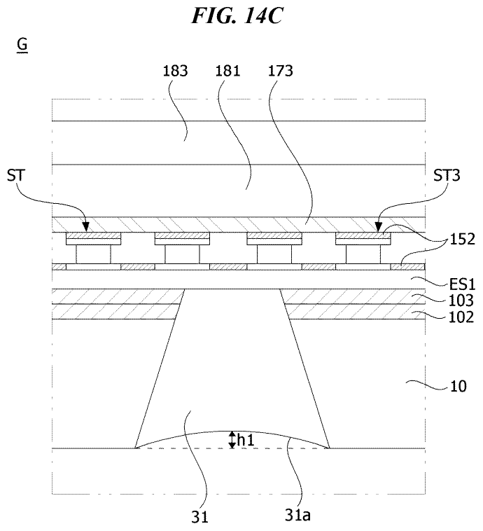

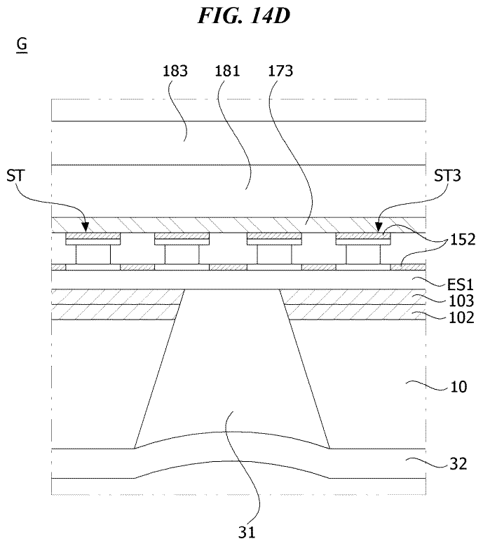

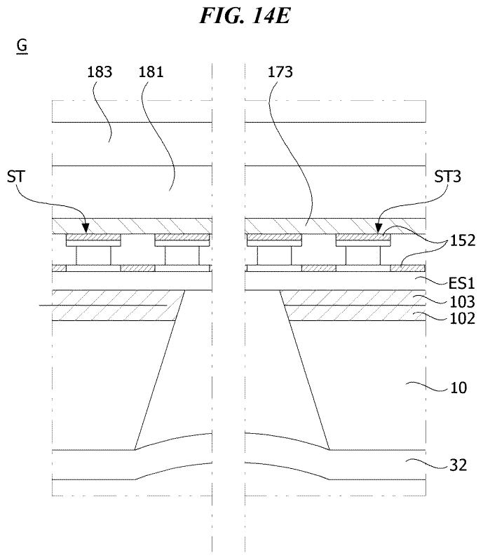

FIG. 13 is a view illustrating the display panel before forming the light-transmitting area. FIGS. 14A to 14E are views illustrating a process of etching the substrate to form the light-transmitting area in the display panel.

Referring to FIGS. 13 and 14A, mask patterns MP1 may be formed on a lower portion a substrate 10. According to the embodiment, a plurality of openings can be formed simultaneously by forming the mask pattern MPI according to the number and shape of first openings to be formed in the substrate 10 and exposing the substrate 10 to an etching solution. In addition, a plurality of panels may be separated from a mother substrate while forming the openings in cach panel.

As shown in FIG. 14B, by bringing the etching solution into contact with the exposed area, the substrate 10 exposed between the mask patterns MPI can be etched. At this time, inorganic insulating layers 102 and 103 formed on the etched substrate 10 can be etched by the etching solution. However, the etching solution does not penetrate into the panel due to a first etch stop layer ES1 disposed on the inorganic insulating layers 102 and 103. The first etch stop layer ES1 may be formed using various organic insulating layers or metal films formed in a display area.

Referring to FIG. 14C, a side coating layer 31 may be filled in a first opening 11 of the substrate 10. Thereafter, when the side coating layer 31 is cured, the side coating layer 31 is contracted by a selected (or predetermined) height hl so that a curvature may be formed on a lower surface 31a of the side coating layer 31. However, the side coating layer 31 may not contract depending on a material.

Referring to FIG. 14D, a back coating layer 32 may be entirely formed on a lower surface of the substrate 10 and the lower surface of the side coating layer 31. However, the present disclosure is not necessarily limited thereto, and the back coating layer 32 may be formed only on the lower surface of the substrate 10.

Referring to FIG. 14E, a light-transmitting area TA may be formed by irradiating a laser to the first opening of the substrate 10. At this time, the first etch stop layer ES1 and a third protruding pattern ST3 disposed above the substrate 10 may be cut by a laser. According to the embodiment, a contact area between the protruding pattern ST and the inorganic insulating layer is increased so that a phenomenon in which the inorganic insulating layer is delaminated during laser irradiation can be improved.

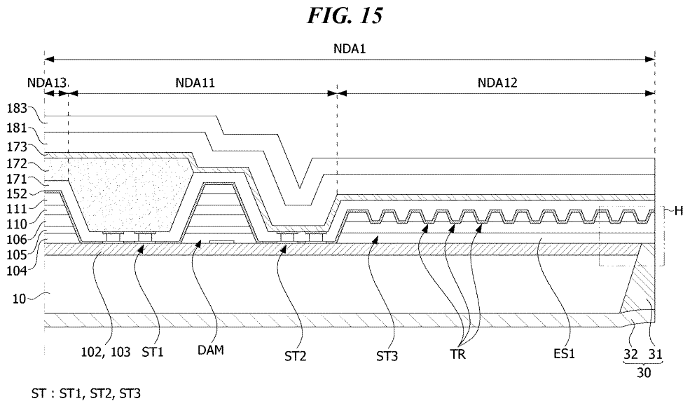

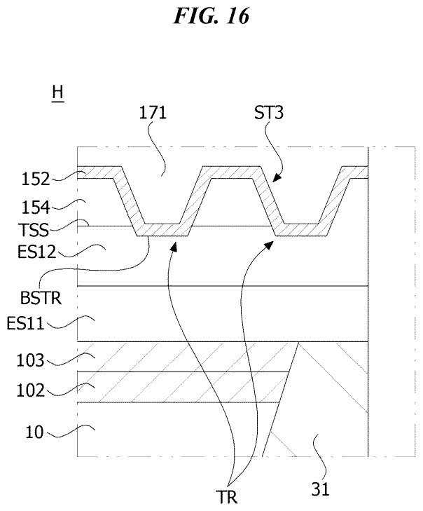

FIG. 15 is a view illustrating a display device according to a second embodiment of the present disclosure. FIG. 16 is an enlarged view of portion H of FIG. 15.

Referring to FIG. 15, a plurality of protruding patterns ST may be disposed in a first non-display area NDA1. The protruding pattern ST is formed to have an undercut shape, so that a light-emitting stack formed in the first non-display area NDA1 may be disconnected.

The plurality of protruding patterns ST may include a first protruding pattern ST1 and a second protruding pattern ST2 disposed in a moisture-permeating prevention area NDA11, and a third protruding pattern ST3 disposed in a dummy area NDA12. A plurality of first protruding patterns ST1 may be disposed between a display area and a dam DAM, and a plurality of second protruding patterns ST2 may be disposed between the dam DAM and the dummy area NDA12.

According to the embodiment, the first protruding pattern ST1 and the second protruding pattern ST2 may have the same shape, but the third protruding pattern ST3 may have a different shape. As described with reference to FIG. 11, in each of the first protruding patterns ST1 and the second protruding patterns ST2, a first pattern layer ML1, a second pattern layer ML2, and a third pattern layer ML3 may be sequentially stacked.

The first pattern layer ML1 and the third pattern layer ML3 may be made of a titanium (Ti) material, and the second pattern layer ML2 may be made of an aluminum (Al) material. The first protruding pattern ST1 and the second protruding pattern ST2 according to the embodiment may be made of the same material as a source electrode or a connection electrode 145 in the display area. That is, the plurality of protruding patterns ST may be formed as a dummy layer when the connection electrode 145 is formed, and then the dummy layer may be separated into the plurality of protruding patterns ST. At this time, the second pattern layer ML2 may be etched relatively more due to a difference in etching speed. Accordingly, a width of the second pattern layer ML2 may be smaller than a width of the third pattern layer ML3, thereby having an undercut shape.

The third protruding pattern ST3 may be disposed on a first sub-layer ES11 and a second sub-layer ES12. The first sub-layer ES11 may be the same layer as the first planarization layer in the display area, and the second sub-layer ES12 may be the same layer as the second planarization layer in the display area.

The third protruding pattern ST3 may be formed using a bank layer 154 disposed on the second sub-layer ES12. According to the embodiment, a light-emitting stack 152 has an uneven shape due to the third protruding pattern ST3, so that a moisture penetration path can be formed to be long. However, the present disclosure is not necessarily limited thereto, and the light-emitting stack may be disconnected by forming the third protruding pattern ST3 in an undercut shape.

As shown in FIG. 15, the light emitting stack 152 may be shaped such that it has a plurality of trenches (or trench portions) TR in the dummy area NDA12. Here, the light emitting stack 152 is continuously and contiguously connected in the dummy area NDA12.

Referring to FIG. 16, the trench portion TR of the light emitting stack 152 has a bottom surface BSTR. In some embodiments, the bottom surface BSTR of the trench portion TR extends into the etch stop layer ES12. For example, the etch stop layer ES12 has a top surface TSS. As shown in FIG. 16, the bottom surface BSTR of the trench portion TR extends into the etch stop layer ES12 such that the bottom surface BSTR is below the top surface TSS.

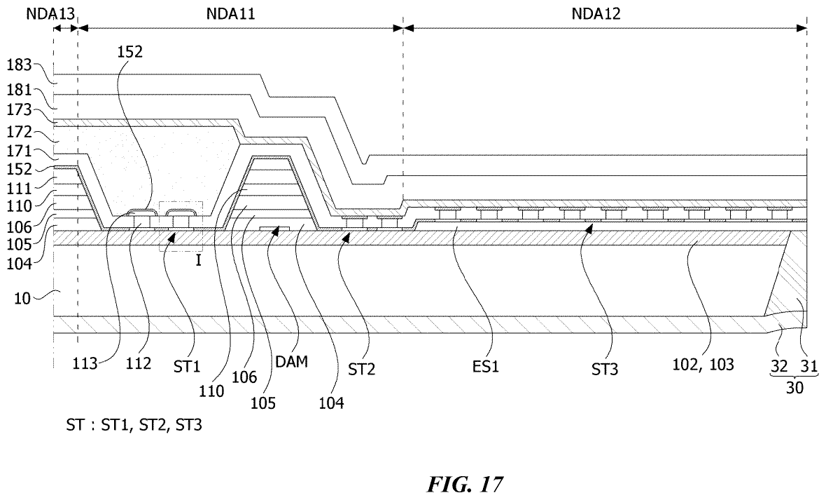

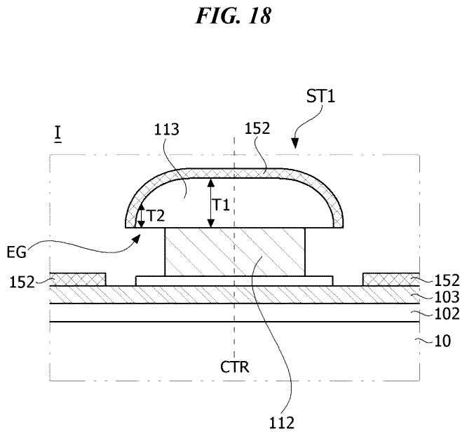

FIG. 17 is a view illustrating a display device according to a third embodiment of the present disclosure. FIG. 18 is an enlarged view of portion I of FIG. 17.

Referring to FIG. 17, a plurality of protruding patterns ST may be disposed in a first non-display area NDA1. The protruding pattern ST is formed to have an undercut shape, so that a light-emitting stack 152 formed in the first non-display area NDA1 may be disconnected.

The plurality of protruding patterns ST may include a first protruding pattern ST1 and a second protruding pattern ST2 disposed in a moisture-permeating prevention area NDA11, and a third protruding pattern ST3 disposed in a dummy area NDA12. A plurality of first protruding patterns ST1 may be disposed between a display area and a dam DAM, and a plurality of second protruding patterns ST2 may be disposed between the dam DAM and the dummy area NDA12.

According to an embodiment, the first protruding pattern ST1 and the second protruding pattern ST2 may have different shapes, and the second protruding pattern ST2 and the third protruding pattern ST3 may have the same shape.

As shown in FIG. 11, in each of the second protruding patterns ST2 and the third protruding patterns ST3, a first pattern layer ML1, a second pattern layer ML2, and a third pattern layer ML3 may be sequentially stacked. The first pattern layer ML1 and the third pattern layer ML3 may be made of a titanium (Ti) material, and the second pattern layer ML2 may be made of an aluminum (Al) material. A width of the third pattern layer ML3 may be formed to be greater than a width of the second pattern layer ML2, thereby having an undercut shape.

The first protruding pattern ST1 may include a 1-1 pattern layer 112 and a 1-2 pattern layer 113, which are disposed on buffer layers 102 and 103. The 1-1 pattern layer 112 may be an inorganic insulating layer, and the 1-2 pattern layer 113 may be an organic insulating layer. As an example, the 1-1 pattern layer 112 may be the same layer as the upper interlayer insulating layer in the display area, and the 1-2 pattern layer 113 may be the same layer as the second planarization layer. However, the 1-1 pattern layer 112 and the 1-2 pattern layer 113 may be formed by using various inorganic/organic insulating layers. In addition, both the 1-1 pattern layer 112 and the 1-2 pattern layer 113 may be formed as inorganic insulating layers or organic insulating layers.

A curvature may be formed on an upper surface of the 1-2 pattern layer 113. This may be formed by isotropic etching of the organic insulating layer. However, the present disclosure is not necessarily limited thereto, and the upper surface of the 1-2 pattern layer may be a flat surface.

Referring to FIG. 18, a thickness of the 1-2 pattern layer 113 becomes thicker from an edge EG of the first protruding pattern ST1 to a center CTR of the first protruding pattern ST1. For example, the 1-2 pattern layer 113 has semi-circular cross section and as the 1-2 pattern layer 113 gets closer to the edge EG from the center CTR, the thickness decreases. That is, thickness T1 adjacent to the center CTR is greater than thickness T2 adjacent to the edge EG.

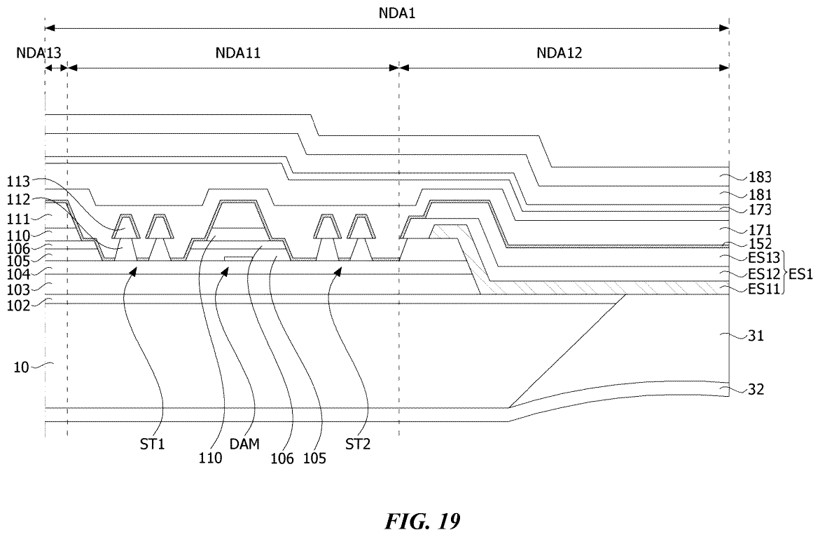

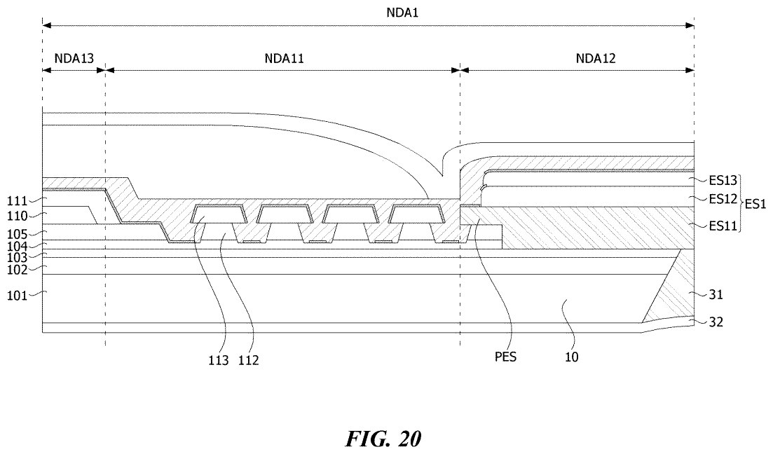

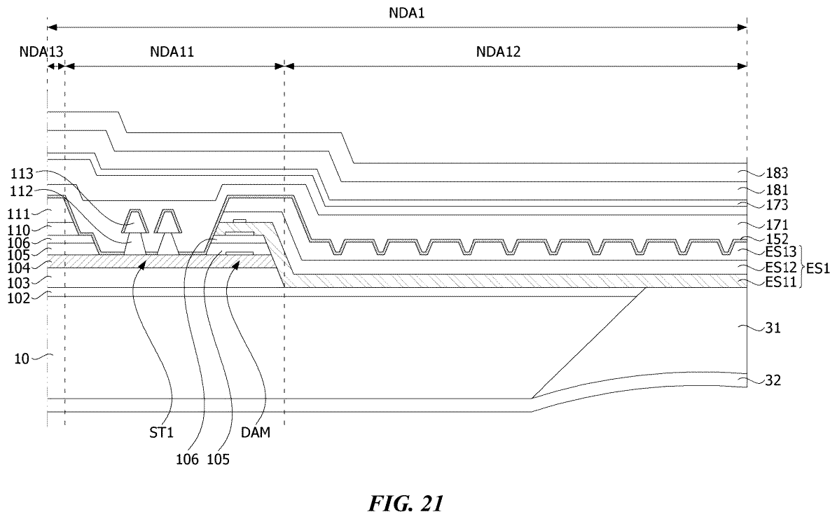

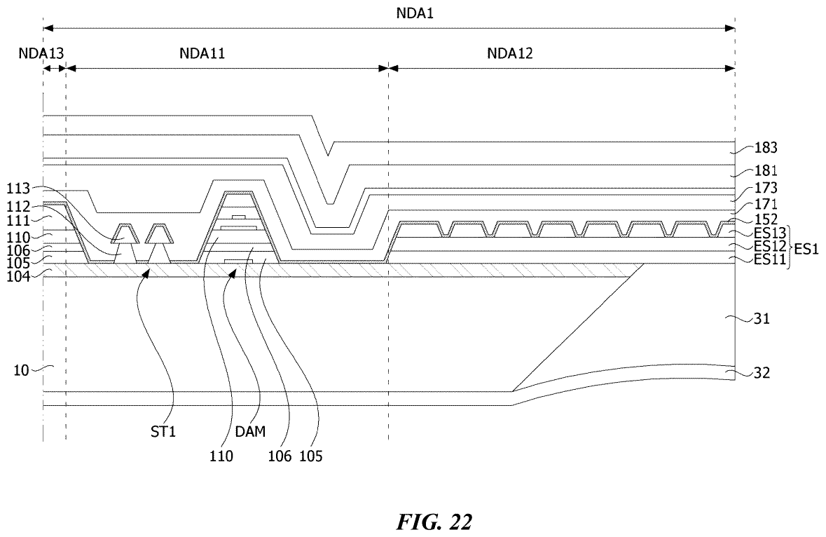

FIG. 19 is a view illustrating a display device according to a fourth embodiment of the present disclosure. FIG. 20 is a view illustrating a display device according to a fifth embodiment of the present disclosure. FIG. 21 is a view illustrating a display device according to a sixth embodiment of the present disclosure. FIG. 22 is a view illustrating a display device according to a seventh embodiment of the present disclosure.

Referring to FIG. 19, a plurality of first protruding patterns ST1 and a plurality of second protruding patterns ST2 may be formed in a moisture-permeating prevention area NDA11. Each of the plurality of first protruding patterns ST1 and the plurality of second protruding patterns ST2 includes an upper portion having a trapezoidal shape, and is formed in an undercut structure, so that a light-emitting stack 152 may be disconnected. In particular, each of the plurality of first protruding patterns ST1 and the plurality of second protruding patterns ST2 includes a trapezoidal cross-sectional shape.

A first sub-layer ES11, a second sub-layer ES12, and a third sub-layer ES13 may be formed in a dummy area NDA12. The first sub-layer ES11 may be the same layer as the first planarization layer in the display area, the second sub-layer ES12 may be the same layer as the second planarization layer in the display area, and the third sub-layer ES13 may be the same layer as the bank layer in the display area. However, the present disclosure is not necessarily limited thereto, and the first to third sub-layers ES11, ES12, and ES13 may be formed of various organic insulating layers and metal layers that are corrosion resistant to a hydrofluoric acid solution. Referring to FIG. 20, a first sub-layer ES11 has a protrusion PES protruding toward a display area and thus has an undercut shape, so that a light-emitting stack 152 may be disconnected.

Referring to FIG. 21, a first etch stop layer ES1 may be formed to extend from a dam DAM. With this configuration, a length of the first etch stop layer ES1 is increased, thereby securing a relatively sufficient dummy area NDA12. Alternatively, as shown in FIG. 22, a first etch stop layer ES1 may be separated from a dam DAM. An uneven portion is formed in a third sub-layer ES13, so that a path through which moisture penetrates along a light-emitting stack may be formed to be long. In addition, a groove formed in the third sub-layer ES13 may be formed in an undercut shape, so that the light-emitting stack may be disconnected.

Since the content of the present disclosure described in the problems to be solved, the problem-solving means, and effects does not specify essential features of the claims, the scope of the claims is not limited to matters described in the content of the disclosure.

According to an embodiment, there is an advantage in process optimization that allows holes of various shapes to be formed simultaneously in a panel when cutting a mother substrate.

In addition, a case in which an etching solution penetrates into a panel when etching a glass substrate can be prevented.

In addition, a case in which moisture penetrates through a light-transmitting area can be prevented.

In addition, a case in which layer delamination occurs around a light-transmitting area can be prevented.

Effects of the present disclosure will not be limited to the above-mentioned effects and other unmentioned effects will be clearly understood by those skilled in the art from the following claims.

While the embodiments of the present disclosure have been described in detail above with reference to the accompanying drawings, the present disclosure is not necessarily limited to these embodiments, and various changes and modifications may be made without departing from the technical spirit of the present disclosure. Accordingly, the embodiments disclosed herein are to be considered descriptive and not restrictive of the technical spirit of the present disclosure, and the scope of the technical spirit of the present disclosure is not limited by these embodiments. Accordingly, the above-described embodiments should be understood to be exemplary and not limiting in any aspect.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area, a light-transmitting area, and a non-display area adjacent to the light-transmitting area;
a circuit portion and a light-emitting element portion disposed in the display area;
an etch stop layer disposed in the non-display area; and
a plurality of protruding patterns disposed in the non-display area, wherein the substrate includes a first opening disposed at a position corresponding to the light-transmitting area, and
wherein the plurality of protruding patterns is disposed on the etch stop layer.

2. The display device of claim 1, wherein each of the plurality of protruding patterns has an undercut shape.

3. The display device of claim 1, wherein each of the plurality of protruding patterns has a same layer structure as a source electrode of the circuit portion.

4. The display device of claim 1, wherein the etch stop layer includes a protrusion protruding toward an inner side of the first opening and
wherein the etch stop layer includes one or more of an organic insulating layer, an inorganic insulating layer, and a metal layer.

5. The display device of claim 1, further comprising a dam disposed in the non-display area,
wherein the plurality of protruding patterns include:
a plurality of first protruding patterns disposed between the display area and the dam;
a plurality of second protruding patterns disposed between the dam and the etch stop layer; and
a plurality of third protruding patterns disposed on the etch stop layer.

6. The display device of claim 5, wherein the plurality of first protruding patterns, the plurality of second protruding patterns, and the plurality of third protruding patterns have the same shape.

7. The display device of claim 5, wherein at least one among the plurality of first protruding patterns, the plurality of second protruding patterns, and the plurality of third protruding patterns includes a different shape or material.

8. The display device of claim 7, wherein the plurality of first protruding patterns includes a metal layer,
wherein the plurality of third protruding patterns includes an organic insulating layer, and
wherein the organic insulating layer of the plurality of third protruding patterns is a dummy layer of a bank layer in the display area.

9. The display device of claim 7, wherein the plurality of first protruding patterns includes an inorganic insulating layer, and wherein the plurality of third protruding patterns includes a metal layer.

10. The display device of claim 9, wherein each of the plurality of first protruding patterns includes:
a first pattern layer; and
a second pattern layer disposed on the first pattern layer,
wherein the first pattern layer is an inorganic insulating layer, and
wherein the second pattern layer is an organic insulating layer.

11. The display device of claim 1, further comprising:
a side coating layer disposed in the first opening;
a back coating layer disposed on a lower surface of the substrate and a lower surface of the side coating layer, and
wherein the lower surface of the side coating layer has a curvature.

12. A display device comprising:
a substrate including a display area, a light-transmitting area, and a non-display area surrounding the light-transmitting area;
a circuit portion and a light-emitting element portion disposed in the display area;
an etch stop layer disposed in the non-display area; and
a plurality of protruding patterns disposed in the non-display area,
wherein the substrate includes a first opening disposed at a position corresponding to the light-transmitting area,
wherein each of the plurality of protruding patterns includes a first pattern layer, a third pattern layer, and a second pattern layer disposed between the first pattern layer and the third pattern layer, and
wherein a width of the second pattern layer is less than a width of each of the first pattern layer and the third pattern layer.

13. The display device of claim 12, wherein the etch stop layer includes a protrusion protruding toward an inner side of the first opening, and
wherein the etch stop layer includes an organic insulating layer or a metal layer.

14. The display device of claim 12, further comprising a dam disposed in the non-display area,
wherein the plurality of protruding patterns include:
a plurality of first protruding patterns disposed between the display area and the dam;
a plurality of second protruding patterns disposed between the dam and the etch stop layer; and
a plurality of third protruding patterns disposed on the etch stop layer,
wherein at least one among the plurality of first protruding patterns, the plurality of second protruding patterns, and the plurality of third protruding patterns includes a different shape or material.

15. A display device comprising:
a substrate including an opening, the substrate having thereon a display area, a light-transmitting area, and a non-display area, the light-transmitting area of the substrate overlapping with the opening of the substrate from a plan view;
an etch stop layer disposed adjacent to the opening; and
a coating layer between the etch stop layer and the substrate,
wherein the etch stop layer is on both the substrate and the coating layer.

16. The display device of claim 15, further comprising:
a polarizing plate on the substrate and the coating layer,
wherein the etch stop layer has an upper surface, a lower surface, and a side surface between the upper surface and the lower surface,
wherein the lower surface of the etch stop layer directly contacts the substrate and the coating layer, and
wherein the polarizing plate directly contacts the upper surface and the side surface of the etch stop layer.

17. The display device of claim 15, further comprising:
a light-emitting stack on the etch stop layer, the light emitting stack having a plurality of trench portions, and
wherein the trench portions of the light-emitting stack extend into the etch stop layer.

18. The display device of claim 15, further comprising:
a dam on the substrate and adjacent to the etch stop layer;
a first protruding pattern adjacent to the etch stop layer, the first protruding pattern between the opening and the dam; and
a second protruding pattern on the substrate and spaced apart from the etch stop layer and the dam,
wherein the dam is between the second protruding pattern and the first protruding pattern.

19. The display device of claim 18, wherein the second protruding pattern includes a first pattern layer and a second pattern layer on the first pattern layer, and
wherein either the first pattern layer or the second pattern layer includes a trapezoidal cross-section.

20. The display device of claim 18, wherein the second protruding pattern includes a first pattern layer and a second pattern layer on the first pattern layer, and
wherein a thickness of the second protruding pattern becomes thicker from an edge of the second protruding pattern to a center of the second protruding pattern.

21. The display device of claim 15, further comprising:
a first protruding pattern adjacent to the etch stop layer, the first protruding pattern including a first pattern layer and a second pattern layer on the first pattern layer, and
wherein at least one of the first pattern layer or the second pattern layer includes a trapezoidal cross-section.
